(19) United States
(12) Patent Application Publication
(10) Pub. No.: US 2004/0129308 A1
(43) Pub. Date: Jul. 8, 2004

(54) Solar thermal electric cells and panels

(76) Inventors: Huan Vinh Luong, Bothell, WA (US); Hsing Kuang Lin, Fairbanks, AK (US); George Stephen Mueller, Hurst, TX (US)

Correspondence Address: Huan Vinh Luong, P.O. Box 1622, Bothell, WA, 98041, US

(21) Appl. No.: 10/336,360

(22) Filed: Jan. 4, 2003

(51) Int. Cl. H01L 35/00; H01L 37/00; H01L 35/30

(52) U.S. Cl. 136/205

(57) ABSTRACT

This invention relates mainly to a method for constructing low cost solar electric cells and panels. The Seeback effect is used in the conversion of solar heat to electricity. Temperature differential between two sides of the solar panel is achieved with the use of thermal absorbing materials and insulating materials. Dissimilar metal wires or strips are used in series and parallel to obtain the appropriate voltage and current.

### TECHNICAL FIELD OF INVENTION

The present invention relates generally to solar electric cell technology. The invention relates in particular to solar electric cells and panels that can convert solar heat to electricity.

### BACKGROUND OF INVENTION

Solar energy has two advantages over conventional energy; it is clean and the resource is boundless. The efficiency of solar electric technology is rapidly approaching the 30% mark, the so-called upper limit. As a result, it is clear that solar electric is a very attractive technology. Currently, solar electric cells and panels are being manufactured via semiconductor technology, which requires the use of high temperature processes (400-1400 degrees C.), and high vacuum systems. For these reasons, the production cost is quite high.

We are taking an alternative approach to harnessing solar energy, by making affordable solar electric cells and panels that can be produced easily. Our invention deals with low cost solar cells and panels that can be used to produce electricity from solar heat. Our idea is to create solar cells and panels that absorb the heat of the sun and convert it into electricity that can be stored in batteries or can be used for other operations. As in semiconductor solar cell, our solar electric cells can be combined to form solar panels of various sizes for various applications.

### DESCRIPTION OF THE INVENTION

Our invention utilizes the concept of the Seebeck effect, which was discovered by Thomas Seebeck in 1821. This effect states that when two dissimilar metals are brought together at two ends, and if one end is heated, current will flow in the circuit. This idea of producing electricity relies on the fact that the two ends of the metal pair joints are at different temperatures.

For the last two decades, thermal absorbing material development has been advancing in a rapid pace. As a result, we now can use these materials to keep one side of the Seebeck circuit at a high temperature, while maintaining one side at a lower temperature. This means it is now possible to apply the Seebeck effect to construct solar thermal electric cells and panels that do not requires semiconductor technology.

In our invention, the solar electric cell consists of two dissimilar metals in the form of wire, strip, mesh or any other shape, joined together in series and parallel fashions. A layer of insulating material separates the two sides of the metal pair joints. On one side, the joints are exposed to the air, cooling environment or coated with insulating material to keep the temperature low. The other side, the joints are either coated or embedded in a layer of thermal absorbing material to keep the temperature high. When the thermal absorbing material absorbs heat, it causes the temperature to rise while leaving the opposite side at air or cooler temperature. As a result, continuous current is produced, and can be used to charge batteries or can be used for other operations.

By connecting the metal joints in series and in parallel, the current and voltage can be adjusted. When a higher current is needed, larger metal strips can be used instead of small wires, at a given temperature differential between the two sets of joints. When a large number of wires and strips or any other shape or forms of metals are used, enough voltage and current can be produced for a particular operation. Higher voltage can also be obtained by increasing the temperature differential. The preferred dissimilar metal pair is selected from a pool of iron, copper, manganese, nickel, chromium, aluminum, magnesium, tin, zinc, titanium, gold, silver, platinum group metals and their alloys, although other metals and alloys can also be used. The uses of electrically conductive non-metal materials such as graphite and graphite mixtures with other conductive materials are not precluded.

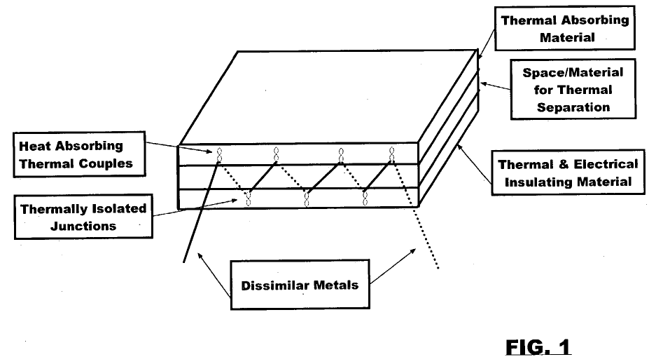

By way of illustration, an example of the invention is shown in FIG. 1. The illustration outlines one approach to the construction of the solar electric cell. The shapes, material types and amount of metals used depend on the actual need.

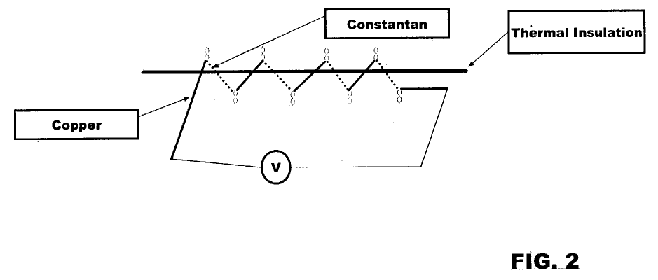

By way of an example, when a copper wire and a constantan wire are connected together, they form one joint. When six of these joints are connected in series, we have three joints maintained at a higher temperature and three joints at a lower temperature. We can complete the circuit by connecting a voltmeter to the series (FIG. 2). When the two sides are conditioned so that one side has higher temperature than the other, a voltage will register on the voltmeter. In one experiment we kept the lower temperature side at 14 degrees C., and kept the higher temperature side at 20 degrees C. The voltmeter registered 0.113 mV. In another experiment, we added four more joints to the circuit. This time the voltmeter registered 0.165 mV. This is a predictable increase in voltage, and it indicates that we can increase the voltage by increasing the number of joints.

It is important to point out that the voltage of the circuit also depends on the temperature differential between the high and low temperature joints. In one experiment, a ten joints system was set up. The five low temperature joints was set at 14 degrees C., while the temperature of the five high temperature joints changes. The result is listed in Table 1. From this table, it is clear that the voltage increases with the increase of the temperature differential of the two sides. It is clear that the proposed solar thermal electric cells and panels will be advantageous when operated with the high temperature joints maintained at a temperature as high as solar energy can provide. It is not unusual that the solar energy can heat the thermal absorbing material to several hundred degrees C.

TABLE 1
Effect of temperature differential on voltage

| High temperature joints | Low Temperature joints | Voltage |
|---|---|---|
| 20 degrees C. | 14 degrees C. | 0.165 mV |
| 23 degrees C. | 14 degrees C. | 0.273 mV |
| 26 degrees C. | 14 degrees C. | 0.505 mV |

What is claimed is:

1. A method for making solar thermal electric cells and panels, comprising the steps of:
a) Joining two dissimilar metals of any shape or form in series and parallel, to form two networks of metal pair joints, each on one side of a board.
b) The board, which separates the two networks of metal pair joints, is made of low thermal conducting material.
c) One network of the metal pair joints is either coated or embedded with thermal absorbing material.
d) One network of the metal pair joints is either exposed to atmosphere, cooling environment or embedded in insulating material.
e) When the thermal absorbing side is heated, current will flow as a result of the temperature differential between the two sides.

2. In claim 1, said cells and panels can range from as small as 1 square inch to as large as needed.

3. In claim 1, said thermal absorbing material, refers to heat absorbing media, and can be either solid, paint like liquid or enclosure of heat absorbing gases such as green house gases.

4. In claim 1, said insulating material, refers to non-heat absorbing media, and can be either solid, paint-like liquid or vacuum enclosure.

5. In claim 1, said dissimilar metals, refer to metals, metal alloys and other electrically conductive materials

6. In claim 1, said temperature differential between the two sides, refers to temperature difference between the thermal absorbing side and the insulating side.

7. In claim 1, the network of the metal pair joints being coated or embedded with thermal absorbing material can be maintained at a temperature as high as solar energy can provide.

8. In claim 1, the network of the metal pair joints being exposed to atmosphere, cooling environment or embedded in insulating material can be maintained at a temperature as low as negative 20 degrees C.
